(19) United States
(12) Patent Application Publication
(10) Pub. No.: US 2026/0068369 A1
(43) Pub. Date: Mar. 5, 2026

(54) UV-LED with Cathode with Electron Gas Layer

(71) Applicant: Silanna UV Technologies Pte Ltd, Singapore (SG)

(72) Inventors: Jordan Roy Nicholls, Hamilton (AU); Petar Atanackovic, Henley Beach South (AU)

(73) Assignee: Silanna UV Technologies Pte Ltd, Singapore (SG)

(21) Appl. No.: 19/294,030

(22) Filed: Aug. 7, 2025

Related U.S. Application Data
(60) Provisional application No. 63/687,490, filed on Aug. 27, 2024.

(51) Int. Cl. H10H 20/833; H10H 20/00; H10H 20/831; H10H 20/857

(52) U.S. Cl. CPC H10H 20/833; H10H 20/062; H10H 20/831; H10H 20/857

(57) ABSTRACT

An LED (e.g., a UV-LED) structure includes a substrate, a first cathode layer, a second cathode layer, a light emitting layer, an anode layer, an anode contact, and a cathode contact. The first cathode layer has a first aluminum composition. The second cathode layer is disposed on top of the first cathode layer and has a second aluminum composition greater than the first aluminum composition. A two-dimensional electron gas (2DEG) layer is formed at an interface between the first cathode layer and the second cathode layer during operation of the LED structure.

### RELATED APPLICATIONS

This application claims priority to U.S. Provisional Ser. No. 63/687,490, filed on Aug. 27, 2024, and entitled “UV-LED with Cathode with Electron Gas Layer”; the content of which is incorporated herein by reference in full.

### BACKGROUND

Ultraviolet light emitting diodes (UV-LEDs) have enormous potential for sterilization, water treatment, scientific analysis and other applications. An example conventional UV-LED structure typically involves a stack of material layers that includes at least a substrate, a cathode layer, a light emitting layer (i.e., an active layer), and an anode layer. In some cases, the cathode layer has to be relatively transparent for the light generated in the light emitting layer to be able to pass through the cathode layer to exit the overall UV-LED structure. Additionally, the cathode layer has to be relatively conductive to properly enable the electrical current to pass therethrough and avoid current crowding. However, simultaneously achieving both high conductivity and high transparency in the cathode structure is a known issue.

### SUMMARY

In some examples, a light emitting diode (LED) structure (e.g., an ultraviolet light emitting diode (UV-LED) structure) includes a substrate, a first cathode layer, a second cathode layer, a light emitting layer, an anode layer, an anode contact, and a cathode contact. The first cathode layer is disposed above the substrate and has a first aluminum composition. The second cathode layer is disposed on top of the first cathode layer and has a second aluminum composition greater than the first aluminum composition. In some examples, the second cathode layer has a first portion having a first thickness; the second cathode layer has a second portion formed by a partial etch through the second cathode layer; and the second portion has a second thickness that is less than the first thickness. The light emitting layer is disposed on top of the first portion of the second cathode layer. The anode layer is disposed on top of the light emitting layer. The anode contact is disposed on top of the anode layer. The cathode contact is disposed on top of the second portion of the second cathode layer. A two-dimensional electron gas (2DEG) layer is formed at an interface between the first cathode layer and the second cathode layer.

In some examples, either or both of the first cathode layer and the second cathode layer may be a short-period superlattice or bulk semiconductor material.

### BRIEF DESCRIPTION OF FIGURES

FIG. 1 is a simplified example of a semiconductor light emitting structure incorporating a cathode structure, in accordance with some examples.

FIGS. 2-5 show a portion of the semiconductor light emitting structure shown in FIG. 1 with aluminum composition graphs, in accordance with some examples.

### DETAILED DESCRIPTION

A semiconductor light emitting structure (e.g., a UV-LED) is disclosed incorporating a cathode structure that has an upper layer with a relatively high aluminum composition (a high-Al layer) so as to achieve relatively high optical transmission (i.e., a first optical transparency). The cathode structure also has a lower layer (beneath and immediately adjacent to the upper layer) with a relatively low aluminum composition (a low-Al layer). Therefore, a two-dimensional electron gas (2DEG) layer is formed at the interface between the upper and lower layers due to a difference in charge between the two cathode layers because of a step up in the Al composition thereof. Additionally, in some examples, the thickness of the lower layer in the vertical dimension (i.e., in the direction of light emission) is relatively small so that the lower optical transmission capability (i.e., a second optical transparency that is lower than the first optical transparency of the upper layer) of this layer does not unduly affect the optical transmission capability of the overall semiconductor light emitting structure. The cathode structure, therefore, has a relatively high optical transparency (to the emitted wavelength) and a relatively high lateral conductivity.

The Al composition can involve any appropriate materials, such as Group III-nitride materials including AlₓGa₁₋ₓN (i.e., AlGaN) where 0≤x≤1, or (InₓAl_{y}Ga_{1-x-y})N (i.e., InAlGaN) where 0≤x≤1, 0≤y≤1, and x+y≤1. Additionally, an “Al composition” can mean the total fraction or percentage of Al with respect to all elements (i.e., including the Al) in the layer, the total fraction or percentage of Al with respect to all other elements (i.e., excluding the Al) in the layer, a ratio of the Al to all Group III elements (i.e., an Al/III ratio including the Al in the Group III, e.g., Al/(Al+Ga+In), or Al/(Al+Ga)), or a ratio of the Al to all other Group III elements (i.e., an Al/III ratio excluding the Al in the Group III, e.g., Al/(Ga+In), or Al/Ga). For example, if a first layer has a higher Al composition than a second (adjacent) layer, then the Al percentage or the Al/III ratio will be greater for that layer compared to the second layer.

The semiconductor light emitting structure described herein can be used in light emitting diodes (LEDs) that emit at short wavelengths (e.g., in the UVC band, or with wavelengths less than 300 nm).

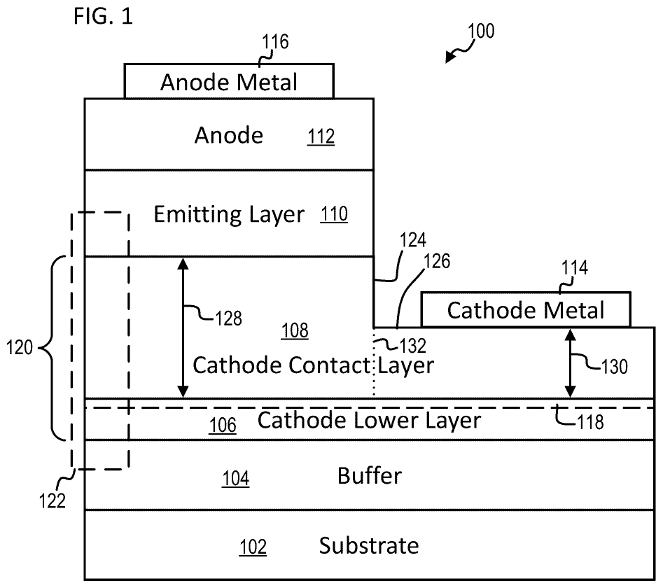

FIG. 1 shows a simplified example of a semiconductor light emitting structure 100 (e.g., a UV-LED device or structure) incorporating a cathode structure, in accordance with some examples. The semiconductor light emitting structure 100 generally includes a substrate 102, a buffer layer 104 disposed on top of the substrate 102, a cathode lower layer 106 (i.e., a first cathode layer) disposed above the substrate 102 or on top of the buffer layer 104, a cathode contact (or upper) layer 108 (i.e., a second cathode layer) disposed on top of the cathode lower layer 106, a light emitting layer 110 (i.e., an active layer) disposed on top of a first (lateral) portion 124 of the cathode contact layer 108, an anode layer 112 (e.g., a p-contact layer) disposed on top of the light emitting layer 110, a cathode metal layer 114 (i.e., an n-metal layer or cathode contact) disposed on top of a second (lateral) portion 126 of the cathode contact layer 108, and an anode metal layer (or anode contact) 116 disposed on top of the anode layer 112, among other elements not shown for simplicity. In some examples, the buffer layer 104, the cathode lower layer 106, the cathode contact layer 108, the light emitting layer 110, and the anode layer 112 all comprise semiconductor materials, and the semiconductor materials can vary between different layers. Additionally, the cathode lower layer 106 and the cathode contact layer 108 are metal-polar AlGaN or other Al-containing Group III-nitride (III-N) material and form a cathode structure 120, and the semiconductor light emitting structure 100 (except for the cathode metal layer 114 and the anode metal layer 116, i.e., including the substrate 102, the buffer layer 104, the cathode lower layer 106, the cathode contact layer 108, the light emitting layer 110, and the anode layer 112) forms a metal-polar device.

In some examples, the substrate 102 can be many different materials, such as sapphire, SiC, AlN, GaN, silicon, or diamond (or other appropriate material depending on the requirements of the overall structure design or configuration). In some examples, the substrate 102 has a low absorption coefficient to the light emitted from the light emitting layer 110 and/or has a lattice constant that is similar to the material forming the other layers of the semiconductor light emitting structure 100. In some examples, the substrate 102 significantly absorbs light with the wavelengths of interest, but the substrate is thinned or removed during device processing. In some cases, the substrate 102 is thinned locally (i.e., under the other elements of the semiconductor light emitting structure 100) to form windows for the light emitted from the light emitting layer 110 to escape the semiconductor light emitting structure 100, since the light is emitted in the vertical direction from the light emitting layer 110 towards the substrate 102.

In some examples, the buffer layer 104 is from 50 nm to 1000 nm thick, or from 50 nm to 5000 nm thick, and is composed of a semiconductor material that has a low absorption coefficient to the light emitted from the light emitting layer 110 and a lattice constant that is similar to the material forming the other layers of the semiconductor light emitting structure 100. Some examples of materials that can be used for the buffer layer 104 are AlN, AlGaN, and InAlGaN (or other appropriate material depending on the requirements of the overall structure design or configuration). The buffer layer 104 can be a single layer, multiple layers, a superlattice, a graded layer, or a chirped layer in different examples.

In some examples, the cathode lower layer 106 is AlGaN (e.g., for a UV-LED) or other ternary polarized materials (e.g., a Group III-nitride). In some examples, the cathode lower layer 106 has an Al composition of about 80% or about 75-85%. In some examples, the cathode lower layer 106 is not doped (i.e., intrinsically doped, e.g., i-AlGaN) or not intentionally doped (i.e., no extrinsic dopant is intentionally added, but impurities can be unintentionally added which may in some cases act as dopants). In other examples, the cathode lower layer 106 is partially or entirely doped n-type (e.g., n-AlGaN, using an extrinsic dopant like Si, Ge or Se).

In some examples, the cathode contact layer 108 is AlGaN (e.g., for a UV-LED) or other ternary polarized materials (e.g., a Group III-nitride). In some examples, the cathode contact layer 108 has an Al composition of about 90% or about 85-95%. In some examples, the cathode contact layer 108 is doped n-type (e.g., n-AlGaN, using an extrinsic dopant like Si, Ge or Se), which aids with contact formation with the cathode metal layer 114. The cathode contact layer 108 has the first (lateral) portion 124 that has a first thickness (in the vertical direction shown by arrow 128) and the second (lateral) portion 126 that has a second thickness (in the vertical direction shown by arrow 130) that is less than the first thickness. (The first portion 124 is shown laterally distinguished from and adjacent to the first portion 126 by a dotted line 132.) The cathode contact layer 108 is originally formed with the first thickness throughout, and then the second portion is formed by a partial etch through the cathode contact layer 108 down to the second thickness. In some examples, the original first thickness of the cathode contact layer 108 is sufficient to give an adequate margin for the etching process, so that the etching process does not have to be exact to a high tolerance, since some etch processes are accurate only to about 10-100 nm depending on the type of process and level of uniformity required across a given wafer diameter. The etching process etches down through the anode layer 112, the light emitting layer 110, and the cathode contact layer 108 to form a mesa on which the anode metal layer 116 is formed and an exposed surface of the second portion 126 of the cathode contact layer 108 on which the cathode metal layer 114 is formed. Additionally, in some examples, the first thickness of the first portion 124 is sufficient to aid in reducing the lateral resistivity of the cathode contact layer 108. In some examples, the first thickness (arrow 128) of the first portion 124 is about 50nm to about 5-10μm, and the second thickness (arrow 130) of the second portion 126 depends primarily on an error margin of the specific etch process being used (e.g., almost the same as the first thickness, approximately half of the first thickness, more than half of the first thickness, or less than half of the first thickness).

In some examples, the light emitting layer 110 contains semiconductor materials configured to emit light during operation of the semiconductor light emitting structure 100. In some examples, the light emitting layer 110 can contain one or more narrower bandgap wells surrounded by wider bandgap barriers (e.g., in a quantum well structure, a superlattice, or a short-period superlattice (SPSL)), where the bandgaps and thicknesses of the wells and barriers are chosen to emit light with wavelengths less than 300 nm (e.g., in the UVC band). Some examples of materials for the wells and/or barriers of the light emitting layer 110 are GaN, AlN, AlGaN, and InAlGaN (e.g., (AlₓGa₁₋ₓ)N where 0≤x≤1, and (InₓAl_{y}Ga_{1-x-y})N, where 0≤x≤1, 0≤y≤1, and x+y≤1). In some examples, the light emitting layer 110 is not doped (i.e., intrinsically doped, e.g., i-AlGaN) or not intentionally doped (i.e., no extrinsic dopant is intentionally added, but impurities can be unintentionally added which may in some cases act as dopants). The light emitting layer 110 can have a thickness, for example, from less than about 10 nm to 1000 nm, or from 10 nm to 100 nm, or about 50 nm. In some examples, using a superlattice (or an SPSL) for the light emitting layer 110 can be beneficial for light emission and/or light extraction efficiency from the structure.

In some examples, the anode layer 112 is one or more layers of a material with a high conductivity to enable a low contact resistance between the anode metal layer 116 and the light emitting layer 110. The anode layer 112 can be a p-contact layer with a narrow bandgap material (e.g., to provide a high electrical conductivity), or a wide bandgap material (e.g., to reduce secondary absorption of light emitted from the light emitting layer 110). In some examples, the material of the anode layer 112 has a bandgap that provides a low resistance contact and also a low absorption coefficient for the wavelength of light emitted from the light emitting layer 110. Some examples of materials for the anode layer 112 are GaN, AlN, AlGaN, and InAlGaN depending on the specific example. In some examples, the anode layer 112 is doped with a p-type dopant, such as Mg. The thickness of the anode layer 112 can be, for example, from 10 nm to greater than or about equal to 100 nm, or about 40 nm. In some cases, the anode layer 112 can be a superlattice, for example, an SPSL with GaN wells and AlN barriers, or with AlGaN wells and barriers. In some cases, the anode layer 112 can have a graded composition, for example from a first to a second composition of AlₓGa₁₋ₓN throughout the layer.

In some examples, the cathode metal layer 114 (e.g., an n-metal) and the anode metal layer 116 (e.g., a p-metal) contain any combinations of metals that form contacts to the cathode contact layer 108 and the anode layer 112, respectively. Some examples of materials that can be used in the cathode metal layer 114 and/or the anode metal layer 116 are Ti, Al, Ta and Ni. For example, the cathode metal layer 114 and the anode metal layer 116 can include a layer of Ti adjacent to the cathode contact layer 108 or the anode layer 112, followed by a layer of Al. In some examples, the cathode metal layer 114 and the anode metal layer 116 each includes from 1 nm to 10 nm (or about 2 nm) of Ti deposited on the cathode contact layer 108 or the anode layer 112, followed by from 20 nm to 400 nm of Al. The total thickness of the cathode metal layer 114 and the anode metal layer 116 can be from about 20 nm to about 400 nm or 1 micron. In some examples, the cathode metal layer 114 and/or the anode metal layer 116 are annealed, which may form alloys of the metal materials thereof with the material of the cathode contact layer 108 or the anode layer 112, respectively.

A 2DEG layer 118 is generated in a relatively thin region at, near or surrounding the interface between the cathode lower layer 106 and the cathode contact layer 108 (e.g., in some examples, the 2DEG layer 118 is generated within a thin region of the cathode lower layer 106 at, near or immediately adjacent to the cathode contact layer 108 and extending into the cathode contact layer 108 a short distance that is thinner than the region in the cathode lower layer 106) and disposed away from the light emitting layer 110. The 2DEG layer 118 occurs at this interface in the metal-polar AlGaN crystal due to a difference in charge between the cathode lower layer 106 and the cathode contact layer 108 because of a step up in Al composition (i.e., a sudden increase in aluminum percentage) from a first Al composition in the cathode lower layer 106 to a second Al composition (greater than the first Al composition) in the cathode contact layer 108. For example, the cathode contact layer 108 can be AlₓGa₁₋ₓN (i.e., AlGaN) where 0≤x≤1 or (InₓAl_{y}Ga_{1-x-y})N where 0≤x≤1, 0≤y≤1, and x+y≤1, and the cathode lower layer 106 can be AlGaN or InAlGaN with a lower Al content (i.e., with a lower value of x, even zero, in the AlₓGa₁₋ₓN material or a lower value of y, even zero, in the (InₓAl_{y}Ga_{1-x-y})N material) than that of the cathode contact layer 108. In other words, the cathode contact layer 108 can be a layer of Alₓ₁Ga₁₋ₓ₁N, and the cathode lower layer 106 can be a layer of Alₓ₂Ga₁₋ₓ₂N, and x1 can be greater than x2; or the cathode contact layer 108 can be a layer of (InₓAl_{y1}Ga_{1-x-y1})N, and the cathode lower layer 106 can be a layer of (InₓAl_{y2}Ga_{1-x-y2})N, and y1 can be greater than y2. Additionally, higher or lower relative values of x and y can provide different degrees of conductivity and absorption, which can be tuned for different structures (e.g., by changing the composition and/or the thickness of the cathode lower layer 106 and the cathode contact layer 108). In some examples, AlGaN with a lower Al content reduces the bandgap of that layer making it more efficiently doped (e.g., with an extrinsic dopant such as Si, Ge or Se), and the lower Al content of the cathode lower layer 106 will enable that layer to be doped higher and have a higher electrical conductivity (i.e., a first electrical conductivity) than that of the cathode contact layer 108 (i.e., a second electrical conductivity that is lower than the first electrical conductivity). However, the reduced bandgap of the cathode lower layer 106 can also result in greater optical absorption (at the emitted wavelength) by the cathode lower layer 106 compared to that of the cathode contact layer 108. The Al composition of the cathode lower layer 106 and the cathode contact layer 108 can be different depending on the wavelength of light emitted from the semiconductor light emitting structure 100.

This configuration is different from conventional structures, even when multiple layers are employed, because typically the Al composition within the semiconductor light emitting structure 100 decreases from the buffer layer to the light emitting layer. The 2DEG layer 118 provides an additional parallel conduction path (in addition to conduction through the cathode contact layer 108) with high electron mobility that helps to boost the conductivity of the overall structure (e.g., by reducing resistance losses for electrons between the cathode metal layer 114 and the light emitting layer 110) while maintaining optical transparency. In this manner, the cathode structure 120 (i.e., the cathode lower layer 106 and the cathode contact layer 108) can achieve a higher conductivity than is typically possible for a stack which is more transparent to the target wavelength (e.g., in the UVC, or far UVC, band). Additionally, the cathode structure 120 also enables a relatively high optical transparency for the target wavelength.

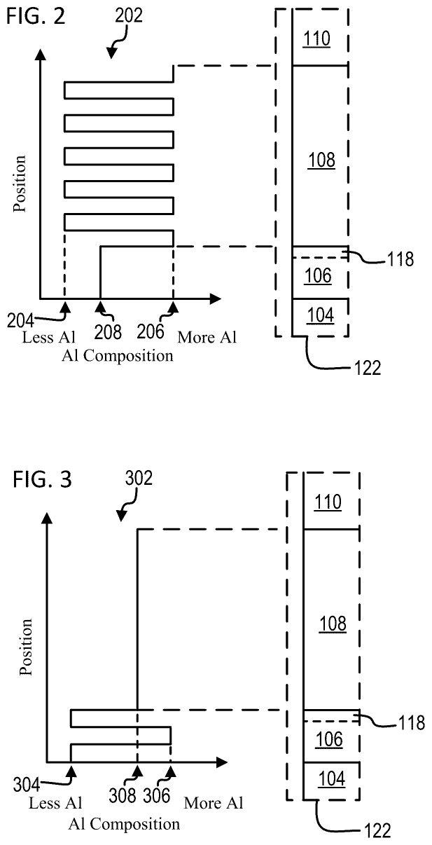

A portion 122 of the semiconductor light emitting structure 100 is reproduced in FIG. 2 alongside a first position v. aluminum composition graph 202. The portion 122 includes parts of the buffer layer 104, the cathode lower layer 106, the cathode contact layer 108, and the light emitting layer 110. The first position v. aluminum composition graph 202 aligns with the cathode lower layer 106 and the cathode contact layer 108 to indicate a first example Al composition within these two layers. The graph indicates, in this example, that the cathode lower layer 106 is formed of bulk semiconductor material (e.g., a single layer of a material of undoped i-AlGaN or n-type doped n-AlGaN) and that the cathode contact layer 108 is formed of a short-period superlattice (e.g., an n-type doped n-SPSL having alternating well layers and barrier layers, which aids with contact formation). A first, lowest or bottom barrier layer of the n-SPSL is disposed on top of the cathode lower layer 106. The n-SPSL of the cathode contact layer 108, thus, has better electrical conductivity than that of the bulk material of the cathode lower layer 106. In some examples, both the well layers and the barrier layers in the n-SPSL are binary (e.g., GaN and AlN, respectively) or ternary (e.g., AlGaN) materials as long as the well layers have a lower Al composition (e.g., at point 204 in the Al composition of the graph) than that of the barrier layers (e.g., at point 206 in the Al composition of the graph). In other words, the well layers have a lower bandgap than that of the barrier layers.

There is still a step up in Al composition at the interface between the cathode lower layer 106 and the cathode contact layer 108, which is the point where the first, lowest or bottom barrier layer of the n-SPSL is disposed on top of the cathode lower layer 106. In one aspect, the step up is from point 208 in the Al composition of the graph for the cathode lower layer 106 to point 206 for the first SPSL layer, a barrier layer, of the cathode contact layer 108. In another aspect, the step up is from the Al composition of the cathode lower layer 106 (e.g., about 80% at point 208 for AlGaN) to a weighted average of the Al composition or effective Al percentage of the cathode contact layer 108 (e.g., between about 70% at point 204 to about 100% at point 206). Thus, the larger Al composition step up at this interface (due to the presence of the barrier layer in the SPSL layer) results in a more positive net charge at the interface than anywhere else in the cathode structure 120, so electrons accumulate at this point to form the 2DEG layer 118. Additionally, the effective bandgap of the cathode contact layer 108 can be greater than that of the cathode lower layer 106 depending on the thicknesses and compositions of the well layers and barrier layers of the cathode contact layer 108. Therefore, this configuration results in the 2DEG layer 118 that provides extra lateral electrical conductivity during operation of the semiconductor light emitting structure 100. Additionally, although there are steps up in Al composition in each SPSL period, there are also steps down, so the net charge is zero for the n-SPSL, except at the interface between the cathode lower layer 106 and the cathode contact layer 108 where the 2DEG layer forms. (The number and thicknesses of the well layers and barrier layers shown in FIG. 2 are provided for illustrative purposes only. Thus, different examples or implementations may have any appropriate number of well layers and barrier layers, and the well layers and barrier layers may have the same or different thicknesses, which can range from 1 monolayer (e.g., about 0.25 nm) to about 10 nm. As an example, the barrier layers may be about 2 nm of AlN (i.e., 100% Al composition) and the well layers may be about 1 nm of AlGaN (e.g., about 70% Al composition).)

The portion 122 of the semiconductor light emitting structure 100 is reproduced in FIG. 3 alongside a second position v. aluminum composition graph 302. The portion 122 includes parts of the buffer layer 104, the cathode lower layer 106, the cathode contact layer 108, and the light emitting layer 110. The second position v. aluminum composition graph 302 aligns with the cathode lower layer 106 and the cathode contact layer 108 to indicate a second example Al composition within these two layers. The graph indicates, in this example, that the cathode lower layer 106 is formed of a short-period superlattice (e.g., an undoped i-SPSL or an n-type doped n-SPSL having alternating well layers and barrier layers) and that the cathode contact layer 108 is formed of bulk semiconductor material (e.g., a single layer of a material of n-type doped n-AlGaN, which aids with contact formation). The cathode contact layer 108 is disposed on top of a last, highest or top well layer of the i-SPSL or n-SPSL of the cathode lower layer 106. An advantage in this example is that the transparency of the cathode lower layer 106 is better than that of the bulk semiconductor material shown in FIG. 2. Additionally, the Al composition step up can be larger when using superlattices (i.e., there is more charge and so more carriers in the 2DEG layer 118), since overall superlattice optical absorption is not the same as the absorption of the lowest Al composition material that the SPSL layers are made from. Thus, the overall superlattice optical absorption can be the same or less than that of the bulk semiconductor material even though the Al composition step up may be larger. In some examples, both the well layers and the barrier layers in the SPSL are binary (e.g., GaN and AlN, respectively) or ternary (e.g., AlGaN) materials as long as the well layers have a lower Al composition (e.g., at point 304 in the Al composition of the graph) than that of the barrier layers (e.g., at point 306 in the Al composition of the graph). In other words, the well layers have a lower bandgap than that of the barrier layers.

There is still a step up in Al composition at the interface between the cathode lower layer 106 and the cathode contact layer 108, which is the point where the cathode contact layer 108 is disposed on top of the last, highest or top well layer of the i-SPSL or n-SPSL of the cathode lower layer 106. In one aspect, the step up is from point 304 in the Al composition of the graph for the top SPSL layer, a well layer, of the cathode lower layer 106 to point 308 for the cathode contact layer 108. In another aspect, the step up is from a weighted average of the Al composition or effective Al percentage of the cathode lower layer 106 (e.g., between about 0% at point 304 to about 100% at point 306) to the Al composition of the cathode contact layer 108 (e.g., about 85% at point 308 for AlGaN). Thus, the larger Al composition step up at this interface (due to the presence of the well layer in the SPSL layer) results in a more positive net charge at the interface than anywhere else in the cathode structure 120, so electrons accumulate at this point to form the 2DEG layer 118. Additionally, the effective bandgap of the cathode lower layer 106 can be lower than that of the cathode contact layer 108 depending on the thicknesses and compositions of the well layers and barrier layers of the cathode lower layer 106. Therefore, this configuration results in the 2DEG layer 118 that provides extra lateral electrical conductivity during operation of the semiconductor light emitting structure 100. Additionally, although there are steps up in Al composition in each SPSL period, there are also steps down, so the net charge is zero for the SPSL, except at the interface between the cathode lower layer 106 and the cathode contact layer 108 where the 2DEG layer forms. (The number and thicknesses of the well layers and barrier layers shown in FIG. 3 are provided for illustrative purposes only. Thus, different examples or implementations may have any appropriate number of well layers and barrier layers, and the well layers and barrier layers may have the same or different thicknesses, which can range from 1 monolayer (e.g., about 0.25 nm) to about 10 nm. As an example, the barrier layers may be about 1.5 nm of AlN (i.e., 100% Al composition) and the well layers may be about 0.25 nm of GaN (i.e., 0% Al composition).)

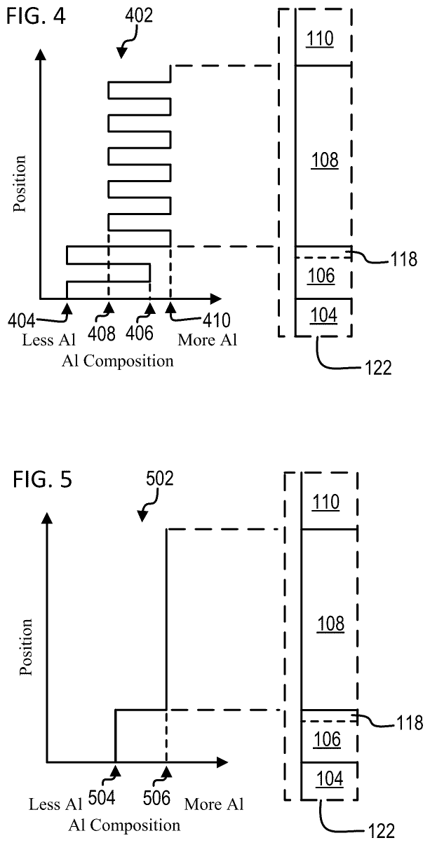

The portion 122 of the semiconductor light emitting structure 100 is reproduced in FIG. 4 alongside a third position v. aluminum composition graph 402. The portion 122 includes parts of the buffer layer 104, the cathode lower layer 106, the cathode contact layer 108, and the light emitting layer 110. The third position v. aluminum composition graph 402 aligns with the cathode lower layer 106 and the cathode contact layer 108 to indicate a third example Al composition within these two layers. The graph indicates, in this example, that the cathode lower layer 106 is formed of a first short-period superlattice (e.g., an undoped i-SPSL or an n-type doped n-SPSL, i.e., a first SPSL having alternating first well layers and first barrier layers) and that the cathode contact layer 108 is formed of a second short-period superlattice (e.g., an n-type doped n-SPSL, i.e., a second SPSL having alternating second well layers and second barrier layers, which aids with contact formation). A first, lowest or bottom barrier layer of the second SPSL is disposed on top of a last, highest or top well layer of the first SPSL of the cathode lower layer 106. An advantage in this example is that the layer conductivity of both layers 106 and 108 and the transparency of the cathode lower layer 106 are better than that of the bulk semiconductor material shown in FIGS. 2 and 3. Additionally, the Al composition step up can be larger, yet the optical absorption thereof can be the same or less, when using both superlattices (i.e., there is more charge and so more carriers in the 2DEG layer 118). In some examples, both the well layers and the barrier layers in both of the SPSLs are binary (e.g., GaN and AlN, respectively) or ternary (e.g., AlGaN) materials as long as the well layers have a lower Al composition (e.g., at point 404 in the Al composition for the cathode lower layer 106 and at point 408 in the Al composition for the cathode contact layer 108) than that of the barrier layers (e.g., at point 406 in the Al composition for the cathode lower layer 106 and at point 410 in the Al composition for the cathode contact layer 108). In other words, the well layers have a lower bandgap than that of the barrier layers.

There is still a step up in Al composition, or a step up in effective Al composition, at the interface between the cathode lower layer 106 and the cathode contact layer 108, which is the point where the first, lowest or bottom barrier layer of the second SPSL is disposed on top of the last, highest or top well layer of the first SPSL. In one aspect, the step up is in absolute Al composition from point 404 in the Al composition of the graph for the last/top SPSL layer, a well layer, of the cathode lower layer 106 to point 410 for the first/bottom SPSL layer, a barrier layer, of the cathode contact layer 108. In another aspect, the step up is from a weighted average of the Al composition or effective Al composition or percentage of the cathode lower layer 106 (e.g., between points 404 and 406) to a weighted average of the Al composition or effective Al composition or percentage of the cathode contact layer 108 (e.g., between points 408 and 410). The larger Al composition step up at this interface (due to the presence of the top well layer in the SPSL of the cathode lower layer 106 and the bottom barrier layer in the SPSL of the cathode contact layer 108) results in a more positive net charge at the interface, in this example, than anywhere else in the cathode structure 120, so electrons accumulate at this point to form the 2DEG layer 118. In some alternative examples, the same Al compositions can be used for the wells/barriers in both the cathode lower layer 106 and the cathode contact layer 108, but the width of the barrier layers in the cathode contact layer 108 are larger than those in the cathode lower layer 106. In this case, the effective Al composition steps up from the cathode lower layer 106 to the cathode contact layer 108, so the 2DEG layer 118 is formed, even though the interface charge itself is unchanged. This alternative technique of forming the 2DEG layer 118 is not only due to the presence of a positive charge at the interface, but also depends on the barrier/well spacing change across the interface, which results in the in-built polarization fields in the superlattice of the cathode contact layer 108 being different from that of the cathode lower layer 106. Additionally, the effective bandgap of the cathode lower layer 106 can be lower than that of the cathode contact layer 108 depending on the thicknesses and compositions of the respective well layers and barrier layers of both the cathode lower layer 106 and the cathode contact layer 108. Therefore, this configuration results in the 2DEG layer 118 that provides extra lateral electrical conductivity during operation of the semiconductor light emitting structure 100. Additionally, although there are steps up in Al composition in each SPSL period of both SPSLs, there are also steps down, so the net charge is zero for both SPSLs, except at the interface (where the compositions of the SPSLs change) between the cathode lower layer 106 and the cathode contact layer 108 where the 2DEG layer forms. (The number and thicknesses of the well layers and barrier layers shown in FIG. 4 are provided for illustrative purposes only. Thus, different examples or implementations may have any appropriate number of well layers and barrier layers for either SPSL, and the well layers and barrier layers may have the same or different thicknesses for either SPSL, which can range from 1 monolayer (e.g., about 0.25 nm) to about 10 nm. As an example, for the cathode lower layer 106 the barrier layers may be about 2nm of AlGaN (e.g., about 85% Al composition) and the well layers may be about 1nm of AlGaN (e.g., about 50% Al composition), and for the cathode contact layer 108 the barrier layers may be about 1 nm AlN (i.e., 100% Al composition) and the well layers may be about 1nm of AlGaN (e.g., about 70% Al composition).)

The portion 122 of the semiconductor light emitting structure 100 is reproduced in FIG. 5 alongside a fourth position v. aluminum composition graph 502. The portion 122 includes parts of the buffer layer 104, the cathode lower layer 106, the cathode contact layer 108, and the light emitting layer 110. The fourth position v. aluminum composition graph 202 aligns with the cathode lower layer 106 and the cathode contact layer 108 to indicate a fourth example Al composition within these two layers. The graph indicates, in this example, that the cathode lower layer 106 is formed of a first bulk semiconductor material (e.g., bulk undoped i-AlGaN or n-type doped n-AlGaN) and that the cathode contact layer 108 is formed of a second bulk semiconductor material (e.g., bulk n-type doped n-AlGaN, which aids with contact formation).

There is a step up in Al composition at the interface between the cathode lower layer 106 and the cathode contact layer 108 (e.g., from point 504 in the Al composition for the cathode lower layer 106 to point 506 for that of the cathode contact layer 108). Therefore, this configuration results in the 2DEG layer 118 that provides extra lateral electrical conductivity during operation of the semiconductor light emitting structure 100.

Additionally, although the cathode lower layer 106 is shown to be significantly thinner than the cathode contact layer 108, it is understood that the present invention is not necessarily so constrained unless explicitly stated in the claims. Instead, the actual thicknesses as well as the relative thicknesses of these two layers may be selected depending on overall design requirements or constraints for the semiconductor light emitting structure 100. Thus, the cathode lower layer 106 and the cathode contact layer 108 may have any appropriate thicknesses. In some examples, since there is generally no need to make the cathode lower layer 106 very thick, it is preferable to form it relatively thin compared to the cathode contact layer 108. Thus, the cathode lower layer 106 has a vertical thickness (i.e., a third thickness) that is smaller than the first thickness (arrow 128) of the cathode contact layer 108. On the other hand, in some examples, the cathode contact layer 108 is formed relatively thick in order to reduce the lateral resistivity (or increase lateral conductivity) thereof.

Furthermore, as used herein, the terms upper, lower, top, bottom, above, below, vertical, and horizontal are relative to the substrate and the other layers of the semiconductor light emitting structure 100. Thus, the vertical direction or dimension is considered to be generally perpendicular to the top or bottom surface of the substrate 102, and the horizontal direction or dimension is considered to be generally parallel to the top or bottom surface of the substrate 102. Additionally, a layer that is further (in the vertical direction from the substrate 102 towards the buffer layer 104) from the substrate 102 than another layer is considered to be the upper layer, and the other layer is considered to be the lower layer. Similarly, a surface of a layer that is further (in the vertical direction from the substrate 102 towards the buffer layer 104) from the substrate 102 than another surface of the same layer (but vertically aligned with each other) is considered to be the top surface of that layer, and the other surface is considered to be the bottom surface. Thus, the upper layer is considered to be above the lower layer, and the lower layer is considered to be below the upper layer.

In some examples, the layers of the semiconductor light emitting structure described herein are grown using molecular beam epitaxy (MBE), metal organic chemical vapor deposition (MOCVD), or hydride vapor phase epitaxy (HVPE). In some examples, subsequent to epitaxially growing the layers of the semiconductor light emitting structure, standard semiconductor fabrication methods can be used to process the semiconductor epitaxial structures, including etching to form mesa structures (e.g., using a dry etch) and metal deposition to deposit the n-and p-metal contacts (e.g., using evaporation or sputtering). In some examples, the cathode contact layer can be processed after epitaxial growth in order to increase the conductivity and/or doping density of the layer. For example, laser or thermal processing can be used to improve the dopant activation in the layer. In some examples, such laser or thermal processing can be performed during the epitaxial growth process. In some examples, ion implantation can also be used to increase the doping density of the cathode contact layer.

Reference has been made in detail to examples of the disclosed invention, one or more examples of which have been illustrated in the accompanying figures. Each example has been provided by way of explanation of the present technology, not as a limitation of the present technology. In fact, while the specification has been described in detail with respect to specific examples of the invention, it will be appreciated that those skilled in the art, upon attaining an understanding of the foregoing, may readily conceive of alterations to, variations of, and equivalents to these examples. For instance, features illustrated or described as part of one example may be used with another example to yield a still further example. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only and is not intended to limit the invention.

What is claimed is:

1. A light emitting diode (LED) structure comprising:
a substrate;
a first cathode layer disposed above of the substrate, the first cathode layer having a first aluminum composition;
a second cathode layer disposed on top of the first cathode layer, the second cathode layer having a second aluminum composition greater than the first aluminum composition, the second cathode layer having a first portion and a second portion, the second portion being laterally adjacent to the first portion;
a light emitting layer disposed on top of the first portion of the second cathode layer;
an anode layer disposed on top of the light emitting layer;
an anode contact disposed on top of the anode layer; and
a cathode contact disposed on top of the second portion of the second cathode layer;
wherein:
a two-dimensional electron gas (2DEG) layer is formed at, near or surrounding an interface between the first cathode layer and the second cathode layer.

2. The LED structure of claim 1, wherein:
the first cathode layer comprises a first short-period superlattice (SPSL); and
the second cathode layer comprises a second SPSL.

3. The LED structure of claim 2, wherein:
the first SPSL has alternating first well layers and first barrier layers;
the second SPSL has alternating second well layers and second barrier layers; and
the interface between the first cathode layer and the second cathode layer is a point where a bottom barrier layer of the second SPSL is disposed on top of a top well layer of the first SPSL.

4. The LED structure of claim 1, wherein:
the first cathode layer comprises a short-period superlattice (SPSL); and
the second cathode layer comprises bulk AlGaN.

5. The LED structure of claim 4, wherein:
the SPSL has alternating well layers and barrier layers; and
the second cathode layer is disposed on top of a top well layer of the SPSL.

6. The LED structure of claim 1, wherein:
the first cathode layer comprises bulk AlGaN; and
the second cathode layer comprises a short-period superlattice (SPSL).

7. The LED structure of claim 6, wherein:
the SPSL has alternating well layers and barrier layers; and
a bottom barrier layer of the SPSL is disposed on top of the first cathode layer.

8. The LED structure of claim 1, wherein:
the first cathode layer comprises a first bulk AlGaN; and
the second cathode layer comprises a second bulk AlGaN.

9. The LED structure of claim 1, wherein:
the LED structure is an ultraviolet light emitting diode (UV-LED) structure.

10. The LED structure of claim 1, wherein:
the light emitting layer emits light with a wavelength less than 300 nm or in a UVC band.

11. The LED structure of claim 1, further comprising:
a buffer layer disposed on top of the substrate;
and wherein:
the first cathode layer is disposed on top of the buffer layer.

12. The LED structure of claim 1, wherein:
the first portion of the second cathode layer has a first thickness;
the second portion of the second cathode layer is formed by a partial etch through the second portion of the second cathode layer; and
the second portion of the second cathode layer has a second thickness that is less than the first thickness.

13. The LED structure of claim 12, wherein:
the first cathode layer has a third thickness that is smaller than the first thickness of the second cathode layer.

14. The LED structure of claim 1, wherein:
the second cathode layer has a first optical transparency; and
the first cathode layer has a second optical transparency that is lower than the first optical transparency of the second cathode layer.

15. The LED structure of claim 1, wherein:
the first cathode layer has a first electrical conductivity; and
the second cathode layer has a second electrical conductivity that is lower than the first electrical conductivity.

16. The LED structure of claim 1, wherein:
the first cathode layer and the second cathode layer form a cathode structure with a metal-polar AlGaN or Group III-nitride material; and
at least the substrate, the first cathode layer, the second cathode layer, the light emitting layer, and the anode layer form a metal-polar device.

17. The LED structure of claim 1, wherein:
the first aluminum composition is about 75-85%; and
the second aluminum composition is about 85-95%.

18. A light emitting diode (LED) structure comprising:
a substrate;
a buffer layer disposed on top of the substrate;
a first cathode layer disposed on top of the buffer layer, the first cathode layer having a first aluminum composition;
a second cathode layer disposed on top of the first cathode layer, the second cathode layer having a second aluminum composition greater than the first aluminum composition, the second cathode layer having a first portion having a first thickness, the second cathode layer having a second portion formed by a partial etch through the second cathode layer, the second portion having a second thickness that is less than the first thickness, and the second portion being laterally adjacent to the first portion;
a light emitting layer disposed on top of the first portion of the second cathode layer;
an anode layer disposed on top of the light emitting layer;
an anode contact disposed on top of the anode layer; and
a cathode contact disposed on top of the second portion of the second cathode layer;
wherein:
a two-dimensional electron gas (2DEG) layer is formed at, near or surrounding an interface between the first cathode layer and the second cathode layer.

19. The LED structure of claim 18, wherein:
the LED structure is an ultraviolet light emitting diode (UV-LED) structure.

20. The LED structure of claim 18, wherein:
the second cathode layer has a first optical transparency; and
the first cathode layer has a second optical transparency that is lower than the first optical transparency of the second cathode layer;
the first cathode layer has a first electrical conductivity; and
the second cathode layer has a second electrical conductivity that is lower than the first electrical conductivity.
